(19) United States
(12) Patent Application Publication
(10) Pub. No.: US 2018/0151394 A1
(43) Pub. Date: May 31, 2018

(54) SUBSTRATE PROCESSING APPARATUS

(71) Applicant: SCREEN Holdings Co., Ltd., Kyoto (JP)

(72) Inventors: Akito HATANO, Kyoto (JP); Toyohide HAYASHI, Kyoto (JP); Koji HASHIMOTO, Kyoto (JP); Kenji KOBAYASHI, Kyoto (JP); Hiroaki TAKAHASHI, Kyoto (JP)

(21) Appl. No.: 15/576,585

(22) PCT Filed: Apr. 26, 2016
(86) PCT No.: PCT/JP2016/063075

§ 371 Date: Nov. 22, 2017

(30) Foreign Application Priority Data
May 26, 2015 (JP) 2015-106065

(51) Int. Cl. H01L 21/67; H01L 21/687; B08B 3/02; B08B 5/02

(52) U.S. Cl. CPC H01L 21/67051; H01L 21/68764; B08B 5/023; B08B 3/024; B08B 3/022

(57) ABSTRACT

A substrate processing apparatus includes a substrate rotating mechanism for rotating a substrate, a nozzle part for discharging droplets of a processing liquid toward a main surface of the substrate, and a nozzle moving mechanism for moving the nozzle part in a direction along the main surface. The nozzle part includes two guide surfaces (511), two gas ejection ports (512), and two processing liquid supply ports (513). The gas ejection port ejects gas along the guide surface, to thereby form a gas flow flowing along the guide surface. The processing liquid supply port is provided in the guide surface, for supplying the processing liquid to between the gas flow and the guide surface. In the nozzle part, assuming that one of the two gas ejection ports is regarded as a first gas ejection port for forming a gas flow which carries the processing liquid as a thin film flow to a lower end edge (516) of the guide surface, the other is a second gas ejection port for forming a gas flow which collides with the processing liquid spattering from the lower end edge. With this configuration, it is possible to discharge a lot of droplets having a uniform particle diameter and thereby appropriately process a substrate.

### TECHNICAL FIELD

The present invention relates to a substrate processing apparatus.

### Background Art

In a process of manufacturing a semiconductor substrate (hereinafter, referred to simply as a “substrate”), conventionally, a substrate processing apparatus which applies droplets of a processing liquid onto a substrate surface has been used. In a substrate processing apparatus disclosed in Japanese Patent Application Laid-Open No. 2004-349501 (Document 1), for example, attached is a so-called external mixing type two fluid nozzle. At one end portion of the two fluid nozzle, an annular gas discharge port is opened, and in the vicinity of a central portion of the gas discharge port, a liquid discharge port is opened. Though pure water discharged from the liquid discharge port goes almost straight, nitrogen gas discharged from the annular gas discharge port goes convergently toward a convergence point outside a casing, and therefore the nitrogen gas and the pure water collide and are mixed with each other at the convergence point, to thereby form a jet of droplets of the pure water.

Further, in a cleaning nozzle attached in a substrate cleaning apparatus disclosed in Patent Publication No. 5261077 (Document 2), a plurality of discharge holes are provided in a wall surface of a tubular body, and a piezoelectric element is affixed onto an external wall surface of a portion of the wall surface, which is opposite to the plurality of discharge holes. By applying an AC voltage to the piezoelectric element, oscillation is given to a cleaning solution inside the tubular body and droplets of the cleaning solution are discharged from the plurality of discharge holes.

Furthermore, Patent Publication No. 2797080 discloses a nozzle which generates droplets to be fine-powdered or vaporized. In the nozzle, a liquid is supplied onto an inclined surface from a supply port, and the liquid is thinly spread by an airflow flowing at high speed along the inclined surface, to become a thin film flow. The thin film flow is accelerated by the airflow and jetted from a tip of the inclined surface into gas, to thereby become fine particle droplets.

In the two fluid nozzle disclosed in Document 1, the volume median diameter ranges, for example, from 10 μm to 16 μm, but a particle diameter distribution of the droplets is relatively large. In recent years, patterns formed on a substrate surface have been further refined, and when there are droplets having a large particle diameter, it is more likely to cause some defects in patterns and the like. On the other hand, in the cleaning nozzle disclosed in Document 2, for example, the average droplet diameter is not smaller than 15 μm and not larger than 30 μm and the distribution of droplet diameter is not larger than 2 μm in 3σ (σ represents a standard deviation), and it is therefore possible to prevent occurrence of some defects in patterns or the like caused by droplets having a large particle diameter. In the cleaning nozzle disclosed in Document 2, however, the number of droplets discharged from a predetermined range in a unit of time is significantly smaller than that in the two fluid nozzle. Therefore, in order to perform processing equivalent to that of the two fluid nozzle, it is necessary to increase the size of the cleaning nozzle, to prolong the cleaning time, and the like.

### SUMMARY OF INVENTION

The present invention is intended for a substrate processing apparatus, and it is an object of the present invention to discharge a lot of droplets having a uniform particle diameter and thereby appropriately process a substrate.

The substrate processing apparatus according to the present invention includes: a substrate rotating mechanism for rotating a substrate; a nozzle part for discharging droplets of a processing liquid toward a main surface of the substrate; and a nozzle moving mechanism for moving the nozzle part in a direction along the main surface. The nozzle part includes: a guide surface; a first gas ejection port for ejecting gas along the guide surface, to thereby form a first gas flow flowing along the guide surface; a processing liquid supply port provided in the guide surface, for supplying the processing liquid to between the first gas flow and the guide surface; and a second gas ejection port for forming a second gas flow which is to collide with the processing liquid spattering from an end portion of the guide surface in the vicinity of the end portion of the guide surface.

By the present invention, it is possible to discharge a lot of droplets having a uniform particle diameter and thereby appropriately process a substrate.

In one preferred embodiment of the present invention, the guide surface is a conical surface around a predetermined central axis, the processing liquid supply port is annular around the central axis, an annular ejection port around the central axis is provided and gas is ejected from the annular ejection port in a direction along the conical surface from a base portion of the conical surface toward a top portion thereof, and a part of the annular ejection port serves as the first gas ejection port and another part of the annular ejection port serves as the second gas ejection port.

In this case, it is preferable that the nozzle part further includes an auxiliary gas ejection port provided in the vicinity of the top portion of the conical surface, for ejecting gas along the central axis.

In another preferred embodiment of the present invention, the nozzle part further includes another guide surface, the guide surface has a linear edge at the end portion, the another guide surface has another edge in parallel with the edge of the guide surface and in proximity to the edge or coincident with the edge, and the second gas ejection port ejects gas in a direction along the another guide surface from an opposite side of the another edge of the another guide surface toward the another edge.

In this case, preferably, the guide surface and the another guide surface include part of a side surface of a plate-like member, and each of the first gas ejection port, the processing liquid supply port, and the second gas ejection port is a slit opened in at least one main surface of the plate-like member and the side surface thereof.

In still another preferred embodiment of the present invention, the nozzle part further includes a tubular guiding part around a predetermined central axis, in the tubular guiding part, a wall thickness gradually decreases as it goes from one end toward the other end thereof, one of an inner peripheral surface and an outer peripheral surface of the tubular guiding part is included in the guide surface and the other is included in another guide surface, the guide surface has an annular edge at the other end, the first gas ejection port and the processing liquid supply port are annular around the central axis, the first gas ejection port ejects gas in a direction along the guide surface from the one end of the tubular guiding part toward the other end thereof, the second gas ejection port is annular around the central axis, and the second gas ejection port ejects gas in a direction along the another guide surface from the one end of the tubular guiding part toward the other end thereof.

In the preferable substrate processing apparatus, the edge of the guide surface is in parallel with the main surface of the substrate.

The nozzle part may further include another processing liquid supply port provided in the another guide surface, for supplying a processing liquid to between the second gas flow and the another guide surface.

In one aspect of the present invention, the substrate processing apparatus further includes a droplet diameter changing part for changing a particle diameter of droplets to be discharged onto the main surface of the substrate from the nozzle part.

In this case, it is preferable that the droplet diameter changing part adjusts a flow rate of gas from the first gas ejection port, or adjusts a flow rate of the processing liquid from the processing liquid supply port.

In another aspect of the present invention, the substrate processing apparatus further includes a first gas flow rate adjusting part for adjusting a flow rate of gas to be ejected from the first gas ejection port; a second gas flow rate adjusting part for adjusting a flow rate of gas to be ejected from the second gas ejection port; and a control part for controlling the first gas flow rate adjusting part and the second gas flow rate adjusting part, to thereby change a discharge direction of droplets.

Preferably, the control part changes the discharge direction while the droplets are spattering from the nozzle part.

In still another aspect of the present invention, the substrate processing apparatus further includes a nozzle up-and-down moving mechanism for moving the nozzle part up and down in a vertical direction perpendicular to the main surface of the substrate.

In this case, the nozzle up-and-down moving mechanism may change a position of the nozzle part in the vertical direction, to thereby change the size of an area in which droplets are to be dispersed on the main surface.

These and other objects, features, aspects and advantages of the present invention will become more apparent from the following detailed description of the present invention when taken in conjunction with the accompanying drawings.

### BRIEF DESCRIPTION OF DRAWINGS

FIG. 1 is a view showing a configuration of a substrate processing apparatus in accordance with a first preferred embodiment;

FIG. 2 is an elevational view showing a nozzle part;

FIG. 3 is a side elevational view showing the nozzle part;

FIG. 4 is an elevational view showing a main-body plate;

FIG. 5 is a flowchart showing an operation flow for processing a substrate;

FIG. 6 is a view showing an exemplary processing of a substrate, which uses the nozzle part;

FIG. 7 is a graph showing a relation between a flow rate of a processing liquid and a flow rate of gas, and a particle diameter of droplets;

FIG. 8A is a view showing another exemplary processing of a substrate, which uses the nozzle part;

FIG. 8B is a view showing another exemplary processing of a substrate, which uses the nozzle part;

FIG. 9A is a view showing still another exemplary processing of a substrate, which uses the nozzle part;

FIG. 9B is a view showing still another exemplary processing of a substrate, which uses the nozzle part;

FIG. 10 is a cross section showing a nozzle part in accordance with a second preferred embodiment;

FIG. 11 is a cross section showing a nozzle part in accordance with a third preferred embodiment; and

FIG. 12 is a view showing another exemplary main-body plate.

### DESCRIPTION OF EMBODIMENTS

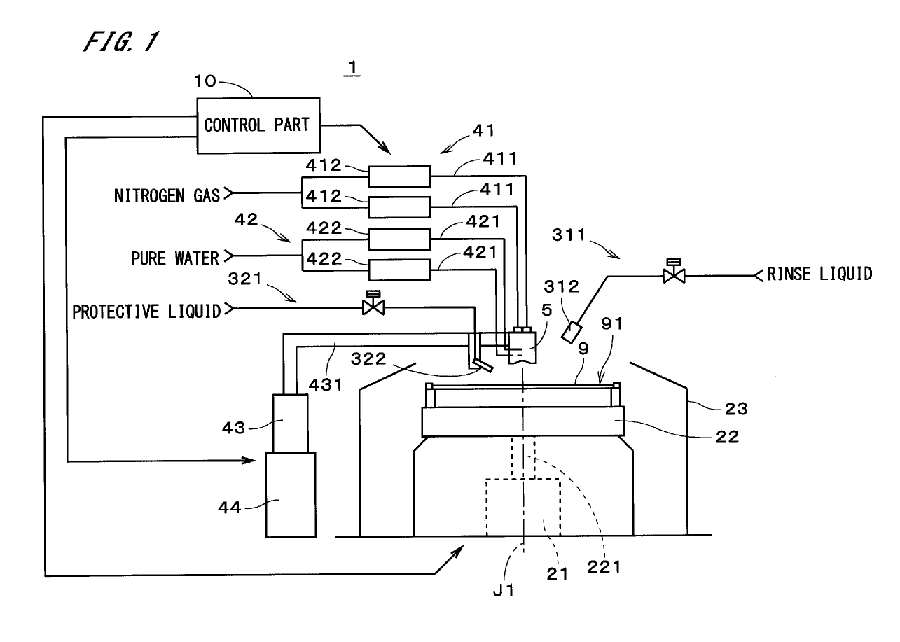

FIG. 1 is a view showing a configuration of a substrate processing apparatus 1 in accordance with the first preferred embodiment of the present invention. Each of constituent elements in the substrate processing apparatus 1 is controlled by a control part 10. The substrate processing apparatus 1 includes a spin chuck 22 which is a substrate holding part, a spin motor 21 which is a substrate rotating mechanism, and a cup 23 surrounding a periphery of the spin chuck 22. A substrate 9 is placed on the spin chuck 22. The spin chuck 22 brings a plurality of grasping members into contact with a peripheral edge of the substrate 9, to thereby grasp the substrate 9. The substrate 9 is thereby held by the spin chuck 22 in a horizontal position. In the following description, a main surface 91 of the substrate 9, which faces upward, is referred to as an “upper surface 91”. On the upper surface 91, formed is a fine pattern.

On a lower surface of the spin chuck 22, connected is a shaft 221 extending in an up-and-down direction (vertical direction). A rotation axis J1 which is a central axis of the shaft 221 is perpendicular to the upper surface 91 of the substrate 9 and passes through a center of the substrate 9. The spin motor 21 rotates the shaft 221. The spin chuck 22 and the substrate 9 are thereby rotated around the rotation axis J1 oriented in the vertical direction. Further, the spin chuck 22 may have a structure for absorbing the back surface of the substrate 9, or the like.

The substrate processing apparatus 1 includes a rinse liquid supply part 311, a rinse liquid nozzle 312, a protective liquid supply part 321, a protective liquid nozzle 322, a gas supply part 41, a processing liquid supply part 42, a nozzle part 5, a nozzle moving mechanism 43, and a nozzle up-and-down moving mechanism 44. In the rinse liquid supply part 311, a supply source of a rinse liquid is connected to the rinse liquid nozzle 312 through a valve. In the protective liquid supply part 321, a supply source of a later-described protective liquid is connected to the protective liquid nozzle 322 through a valve.

The gas supply part 41 has two gas supply pipes 411. Respective one ends of the two gas supply pipes 411 merge with each other and then are connected to a supply source of nitrogen gas which is gas for forming droplets described later. The respective other ends of the two gas supply pipes 411 are connected to the nozzle part 5. Each of the gas supply pipes 411 is provided with a gas flow rate adjusting part 412. In the gas supply part 41, gas other than nitrogen gas may be supplied to the nozzle part 5.

The processing liquid supply part 42 has two processing liquid supply pipes 421. Respective one ends of the two processing liquid supply pipes 421 merge with each other and then are connected to a supply source of pure water which is a processing liquid for forming droplets. The respective other ends of the two processing liquid supply pipes 421 are connected to the nozzle part 5. Each of the processing liquid supply pipes 421 is provided with a processing liquid flow rate adjusting part 422. In the processing liquid supply part 42, a liquid other than pure water may be supplied to the nozzle part 5 as the processing liquid for forming droplets. In the following description, it is assumed that the word “processing liquid” which is simply used means a processing liquid for forming droplets to be supplied to the nozzle part 5.

The protective liquid nozzle 322 and the nozzle part 5 are attached to an arm 431 of the nozzle moving mechanism 43. The nozzle moving mechanism 43 rotates the arm 431 around an axis in parallel with the rotation axis J1, to thereby selectively arrange the protective liquid nozzle 322 and the nozzle part 5 at a facing position which faces the upper surface 91 of the substrate 9 or a waiting position away from the substrate 9 in a horizontal direction. The nozzle up-and-down moving mechanism 44 moves the protective liquid nozzle 322 and the nozzle part 5 together with the arm 431 up and down in the vertical direction perpendicular to the upper surface 91. The rinse liquid nozzle 312 may be also movable by another nozzle moving mechanism or another nozzle up-and-down moving mechanism, like the nozzle part 5 and the like.

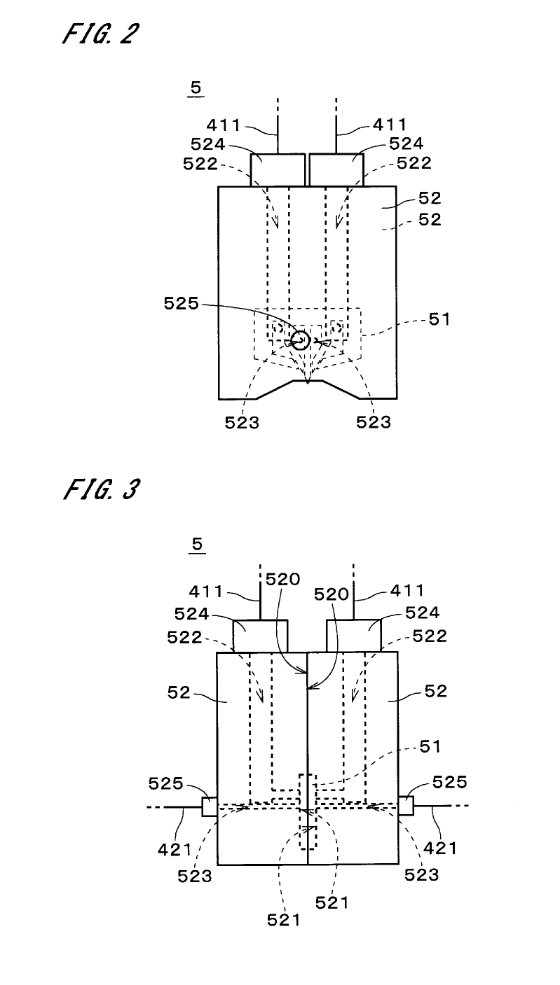

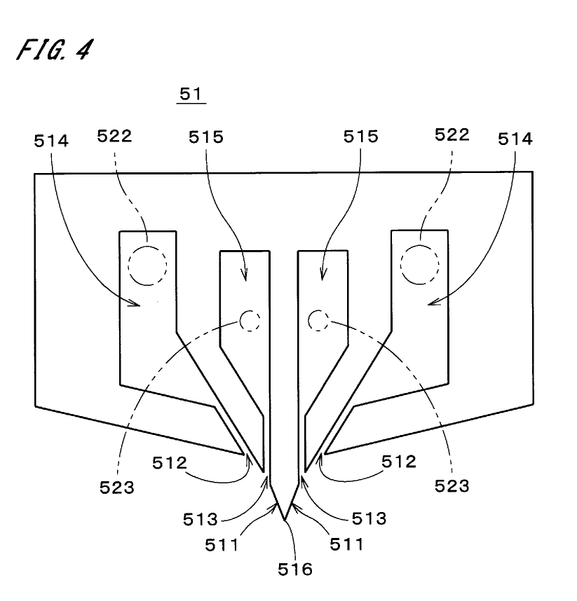

FIG. 2 is an elevational view showing the nozzle part 5, and FIG. 3 is a side elevational view showing the nozzle part 5. As shown in FIGS. 2 and 3, the nozzle part 5 includes a main-body plate 51 and two cover members 52. The main-body plate 51 and the cover members 52 are formed of, for example, polytetrafluoroethylene (PTFE) or quartz. The main-body plate 51 is held, being sandwiched between the two cover members 52 each having a substantially rectangular parallelepiped shape. In detail, in each of the cover members 52, formed is a recessed portion 521 in a facing surface 520 which faces the other cover member 52. With the respective facing surfaces 520 of the two cover members 52 being in contact with each other, the main-body plate 51 is arranged inside the respective recessed portions 521 of the two cover members 52. Actually, the circumference of the main-body plate 51, except the vicinity of a later-described lower end edge 516 (see FIG. 4 described later) in the main-body plate 51, is covered with the two cover members 52.

Each of the two cover members 52 has one gas connecting passage 522 and one processing liquid connecting passage 523. The gas connecting passage 522 connects a connecting part 524 provided on an upper surface of the cover member 52 shown in FIGS. 2 and 3 and a bottom surface of the recessed portion 521 (i.e., a surface inside the recessed portion 521 in parallel with the facing surface 520). To the connecting part 524, connected is the gas supply pipe 411. The processing liquid connecting passage 523 connects a connecting part 525 provided on a surface of the cover member 52, which is opposite to the facing surface 520, and the above-described bottom surface of the recessed portion 521. To the connecting part 525, connected is the processing liquid supply pipe 421.

FIG. 4 is an elevational view showing the main-body plate 51. The main-body plate 51 is a plate-like member having a fixed thickness. The main-body plate 51 includes two guide surfaces 511, two gas ejection ports 512, two processing liquid supply ports 513, two gas chambers 514, and two processing liquid chambers 515. A lower-side end portion of each guide surface 511 has a linear lower end edge 516 extending in a direction perpendicular to the paper of FIG. 4. In the present preferred embodiment, the respective lower end edges 516 of the two guide surfaces 511 are almost coincident with each other. An angle formed by the two guide surfaces 511 with the lower end edge 516 as a vertex is constant at all the positions in a direction in which the lower end edge 516 extends. The angle formed by the two guide surfaces 511 is, for example, an acute angle. Since the direction in which the lower end edge 516 extends is coincident with a thickness direction of the main-body plate 51, the direction is referred to as a “plate thickness direction” in the following description.

In a state where the main-body plate 51 is sandwiched by the two cover members 52 (see FIG. 2), both main surfaces of the main-body plate 51 which are perpendicular to the plate thickness direction are covered with the bottom surfaces of the recessed portions 521 of the cover members 52, except the vicinity of the lower end edge 516. The liquid and the gas cannot be thereby moved among the two gas chambers 514 and the two processing liquid chambers 515. To the two gas chambers 514, the gas connecting passages 522 of the two cover members 52 are connected, respectively (represented by two-dot chain lines in FIG. 4). Therefore, each of the gas chambers 514 can be filled with gas by the gas supply part 41 (see FIG. 1) through the gas supply pipe 411 and the gas connecting passage 522. Similarly, to the two processing liquid chambers 515, the processing liquid connecting passages 523 of the two cover members 52 are connected, respectively (represented by two-dot chain lines in FIG. 4). Therefore, each of the processing liquid chambers 515 can be filled with a processing liquid by the processing liquid supply part 42 through the processing liquid supply pipe 421 and the processing liquid connecting passage 523.

Each of the guide surfaces 511 is a smooth surface which is continuous from the lower end edge 516 to the inside of the gas chamber 514, except a portion of the guide surface 511, which corresponds to the processing liquid supply port 513. The normal of the guide surface 511 is perpendicular to the plate thickness direction. The gas ejection port 512 is formed by a portion of the guide surface 511 between the processing liquid supply port 513 and the gas chamber 514 and a surface facing the portion at equal distance, and continuous from the gas chamber 514. With the supply of gas from the gas supply part 41 to the inside of the gas chamber 514, the gas is ejected from the gas ejection port 512 along the guide surface 511. In other words, the gas is ejected in a direction along the guide surface 511 from an opposite side of the lower end edge 516 (the side of the gas chamber 514) toward the lower end edge 516. A gas flow flowing along the guide surface 511 toward the lower end edge 516 is thereby formed.

The processing liquid supply port 513 is formed by two surfaces perpendicular to the plate thickness direction and in parallel with each other. The processing liquid supply port 513 is continuous from the processing liquid chamber 515 and opened at the guide surface 511. In other words, the processing liquid supply port 513 is provided in the guide surface 511. With the supply of a processing liquid from the processing liquid supply part 42 to the inside of the processing liquid chamber 515, the processing liquid is supplied from the processing liquid supply port 513 to between the above-described gas flow and the guide surface 511. As described above, in the nozzle part 5, both the main surfaces of the main-body plate 51 are covered with the bottom surfaces of the recessed portions 521 of the cover members 52, except the vicinity of the lower end edge 516. Therefore, the bottom surfaces may be regarded as part of the gas ejection port 512 and part of the processing liquid supply port 513.

In the main-body plate 51, the portions of the two guide surfaces 511 in the vicinity of the lower end edge 516 are not covered with any other portion of the main-body plate 51 and are included in side surfaces of the main-body plate 51 itself. In other words, the two guide surfaces 511 include parts of the side surfaces of the main-body plate 51. In the main-body plate 51, all the surfaces except both the main surfaces each have a normal perpendicular to the plate thickness direction. In the manufacture of the main-body plate 51, the two gas ejection ports 512 and the two processing liquid supply ports 513 are formed as fine slits opened in both the main surfaces and the side surfaces by wire electro-discharge machining or the like. Therefore, without any complicate processing, the gas ejection ports 512 and the processing liquid supply ports 513 can be easily formed and the nozzle part 5 can be manufactured at low cost. The main-body plate 51 of the present preferred embodiment includes the lower end edge 516 and has a shape symmetric with respect to a face extending in a longitudinal direction of FIG. 4.

Depending on a design of the nozzle part 5, the two gas ejection ports 512 and the two processing liquid supply ports 513 each may be formed as a slit opened in one main surface and a side surface of the main-body plate 51 by predetermined grooving. Since each of the gas ejection ports 512 and the processing liquid supply ports 513 is a slit opened in at least one main surface and a side surface of the main-body plate 51, it becomes possible to easily manufacture the nozzle part 5.

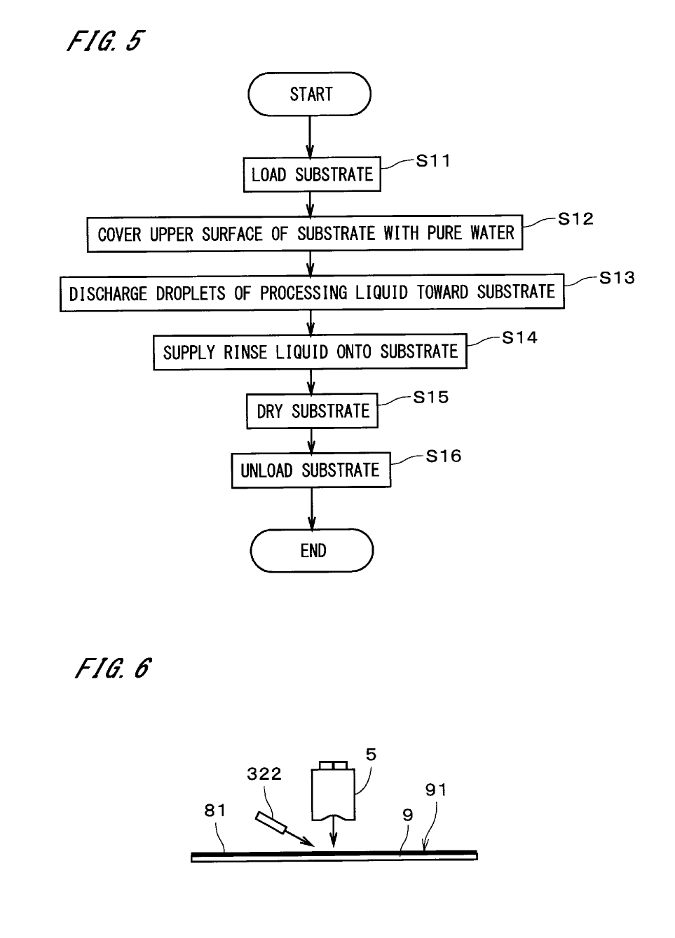

FIG. 5 is a flowchart showing an operation flow for processing a substrate 9 in the substrate processing apparatus 1. First, an unprocessed substrate 9 is loaded into the substrate processing apparatus 1 of FIG. 1 by an external transfer mechanism and held by the spin chuck 22 (Step S11). Subsequently, the rotation of the substrate 9 at the predetermined number of rotation (rotation speed) is started by the spin motor 21. Then, the rinse liquid supply part 311 continuously supplies pure water as a rinse liquid onto a center portion of the upper surface 91 through the rinse liquid nozzle 312 positioned above the substrate 9. The pure water on the upper surface 91 is spread toward an outer edge portion by the rotation of the substrate 9 and the pure water is supplied to the entire upper surface 91. The upper surface 91 is thereby covered with the pure water (Step S12). The supply of the pure water is continued for a predetermined time and then stopped.

Subsequently, the nozzle moving mechanism 43 arranges the nozzle part 5 and the protective liquid nozzle 322 at the facing position which faces the upper surface 91 of the substrate 9. Then, the gas supply part 41 continuously supplies gas into the gas chamber 514 (see FIG. 4) of the nozzle part 5, and the processing liquid supply part 42 continuously supplies the processing liquid into the processing liquid chamber 515 of the nozzle part 5. The gas ejected from each of the gas ejection ports 512 forms a gas flow flowing along the guide surface 511 and the processing liquid supply port 513 supplies the processing liquid to between the gas flow and the guide surface 511. The processing liquid is spread between the gas flow and the guide surface 511 to form a thin film flow, and spatters at the lower end edge 516, away from the guide surface 511.

Herein, as described earlier, in the nozzle part 5, the two guide surfaces 511 are provided and both the guide surfaces 511 share the lower end edge 516. Paying attention to the processing liquid flowing along the one guide surface 511 and spattering from the lower end edge 516, the gas flow flowing along the other guide surface 511 collides with the processing liquid in the vicinity of the lower end edge 516. In other words, assuming that one of the two gas ejection ports 512 is regarded as a first gas ejection port which forms the gas flow that is to carry the processing liquid as the thin film flow toward the lower end edge 516, the other gas ejection port is a second gas ejection port which forms the gas flow that is to collide with the processing liquid spattering from the lower end edge 516. A lot of droplets having a uniform particle diameter are thereby generated. Further, the processing liquid flowing along the one guide surface 511 and spattering from the lower end edge 516 also collides, in the vicinity of the lower end edge 516, with the processing liquid flowing along the other guide surface 511 and spattering from the lower end edge 516. It can be understood that in the nozzle part 5, the thin film flows of the processing liquids flowing along the two guide surfaces 511 collide with each other in the vicinity of the lower end edge 516. The droplets generated in the nozzle part 5 go toward the upper surface 91 of the substrate 9. Thus, the droplets of the processing liquid are discharged from the nozzle part 5 toward the upper surface 91 (Step S13).

At that time, as shown in FIG. 6, the protective liquid supply part 321 continuously supplies a protective liquid onto the upper surface 91 through the protective liquid nozzle 322. The protective liquid nozzle 322 is, for example, a straight nozzle and provided inclinedly with respect to the vertical direction so that the protective liquid may be spread in a discharge area of the droplets from the nozzle part 5, on the upper surface 91. Therefore, on the upper surface 91 of the substrate 9, the droplets are discharged from the nozzle part 5 onto an area in which the protective liquid are deposited. In FIG. 6, the reference numeral 81 is given to a film of the protective liquid. The protective liquid is, for example, SC-1 (a mixed liquid containing NH₄OH and H₂O₂). Therefore, the bonding strength between the substrate 9 and extraneous matters such as particles or the like which are deposited on the upper surface 91 of the substrate 9 is weakened by SC-1. In this state, the droplets are sprayed from the nozzle part 5 toward the upper surface 91 and the extraneous matters are physically removed by the collision with the droplets. As a matter of course, depending on the bonding strength between the substrate 9 and the extraneous matters, or the like, the discharge of the protective liquid may be omitted. Further, a protective liquid other than SC-1, such as pure water, carbonated water, or the like, may be used.

Furthermore, when the nozzle moving mechanism 43 shown in FIG. 1 swings the arm 431, the nozzle part 5 and the protective liquid nozzle 322 are moved in a direction along the upper surface 91 of the substrate 9. For example, the discharge area of the droplets from the nozzle part 5 (i.e., the discharge area of the protective liquid from the protective liquid nozzle 322) reciprocates a plurality of times between the center portion of the substrate 9 and the outer edge portion thereof. Moreover, the substrate 9 is rotated at the predetermined number of rotation. The droplets of the processing liquid and the protective liquid are thereby supplied onto the entire upper surface 91 of the substrate 9.

The discharge of the droplets of the processing liquid and the protective liquid is continued for a predetermined time and then stopped.

After the processing of the substrate 9 with the droplets is completed, the nozzle moving mechanism 43 moves the nozzle part 5 and the protective liquid nozzle 322 to the waiting position away from the substrate 9 in the horizontal direction. Then, the rinse liquid supply part 311 continuously supplies the rinse liquid onto the upper surface 91 through the rinse liquid nozzle 312 positioned above the substrate 9 (Step S14). The protective liquid and the like on the upper surface 91 are thereby rinsed off by the rinse liquid. Also during the supply of the rinse liquid, the rotation of the substrate 9 is continued by the spin motor 21. The supply of the rinse liquid is continued for a predetermined time and then stopped.

After the supply of the rinse liquid is completed, the spin motor 21 rotates the substrate 9 at the number of rotation larger than that in the above-described process. The rinse liquid deposited on the upper surface 91 of the substrate 9 is thereby shaken off to the environment by centrifugal force. Consequently, the rinse liquid on the upper surface 91 is removed and the substrate 9 is dried (Step S15). The substrate 9 after being dried is unloaded from the substrate processing apparatus 1 by the external transfer mechanism, and the processing in the substrate processing apparatus 1 is completed (Step S16).

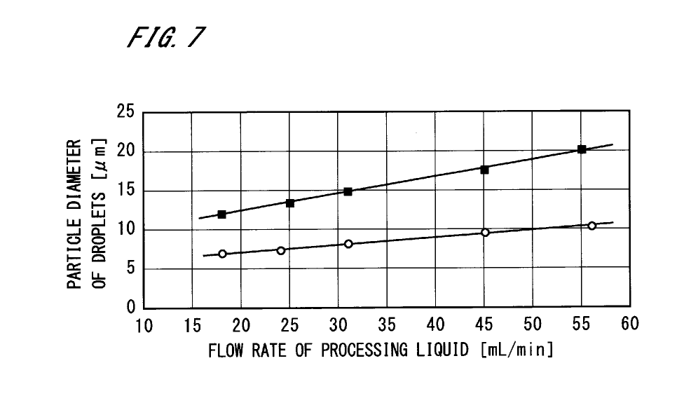

FIG. 7 is a graph showing a relation between a flow rate of the processing liquid in the processing liquid supply port 513 and a flow rate of the gas in the gas ejection port 512, and a particle diameter of the droplets discharged from the nozzle part 5. In FIG. 7, the vertical axis represents an average particle diameter of the droplets and the horizontal axis represents a total flow rate of the processing liquids in the two processing liquid supply ports 513. The flow rates of the processing liquids in the two processing liquid supply ports 513 are equal to each other. Further, in FIG. 7, the solid square represents a particle diameter of the droplets in a case where the flow rate of the gas from each gas ejection port 512 is 30 liters per minute (30 [L/min]), and the blank circle represents a particle diameter of the droplets in a case where the flow rate of the gas is 60 [L/min]. The flow rates of the gases in the two gas ejection ports 512 are equal to each other. The gas is supplied to the gas ejection port 512 by a predetermined pressure. Further, the particle diameter of the droplets is measured by a laser light scattering type particle diameter measurement apparatus at a position at a predetermined distance away from the lower end edge 516.

As shown in FIG. 7, in the case where the flow rate of the gas is 30 [L/min], by gradually increasing the flow rate of the processing liquid from 18 milliliters per minute ([mL/min]) to 55 [mL/min], the particle diameter of the droplets increases from about 12 micrometers (μm) to about 20 μm. Further, in the case where the flow rate of the gas is 60 [L/min], by gradually increasing the flow rate of the processing liquid from 18 [mL/min] to 56 [mL/min], the particle diameter of the droplets increases from about 7 μm to about 10 μm.

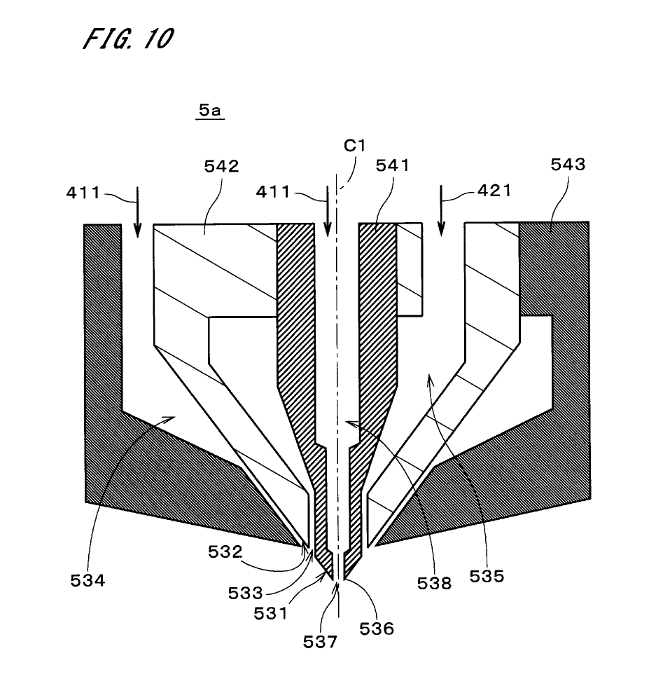

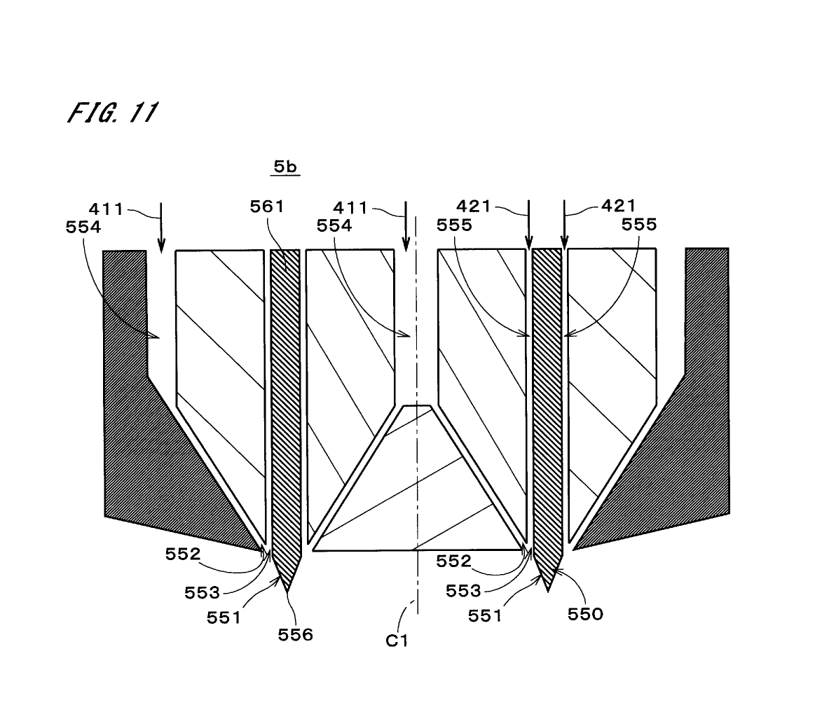

Thus, in the substrate processing apparatus 1, when the gas flow rate adjusting part 412 adjusts the flow rate of the gas from the gas ejection port 512, or when the processing liquid flow rate adjusting part 422 adjusts the flow rate of the processing liquid from the processing liquid supply port 513, it becomes possible to change the particle diameter of the droplets discharged from the nozzle part 5 onto the upper surface 91 of the substrate 9 (the same applies to the later-described nozzle parts 5a and 5b shown in FIGS. 10 and 11, respectively). In other words, the gas flow rate adjusting part 412 and the processing liquid flow rate adjusting part 422 serve as a droplet diameter changing part for changing the particle diameter of the droplets discharged onto the upper surface 91. In the nozzle part 5, actually, the particle diameter distribution of the droplets also becomes relatively smaller. In other words, it is possible to discharge droplets having a uniform particle diameter.

As described above, in the nozzle part 5 of the substrate processing apparatus 1, the processing liquid is supplied to between the guide surface 511 and the gas flow flowing along the guide surface 511. Then, in the vicinity of the lower end edge 516 of the guide surface 511, the gas flow flowing along another guide surface 511 collides with the processing liquid spattering from the lower end edge 516. In the nozzle part 5, it is thereby possible to discharge a lot of droplets having a uniform particle diameter. Further, when the nozzle moving mechanism 43 moves the nozzle part 5 in the direction along the upper surface 91 of the substrate 9 while the spin motor 21 rotates the substrate 9, the entire upper surface 91 of the substrate 9 can be appropriately processed by the droplets of the processing liquid. Moreover, since the lower end edge 516 is in parallel with the upper surface 91 of the substrate 9, the droplets are discharged to a wide range of the upper surface 91, to thereby reduce the time required for the processing of the substrate 9, and uniform processing on the entire discharge area of the droplets can be achieved.

In the substrate processing apparatus 1, since the droplet diameter changing part changes the particle diameter of the droplets discharged onto the upper surface 91, it becomes possible to respond to various conditions of the processing of the substrate 9, such as a case where a fine pattern which is easily collapsed is formed on the upper surface 91, another case where strong physical cleaning is needed, and the like.

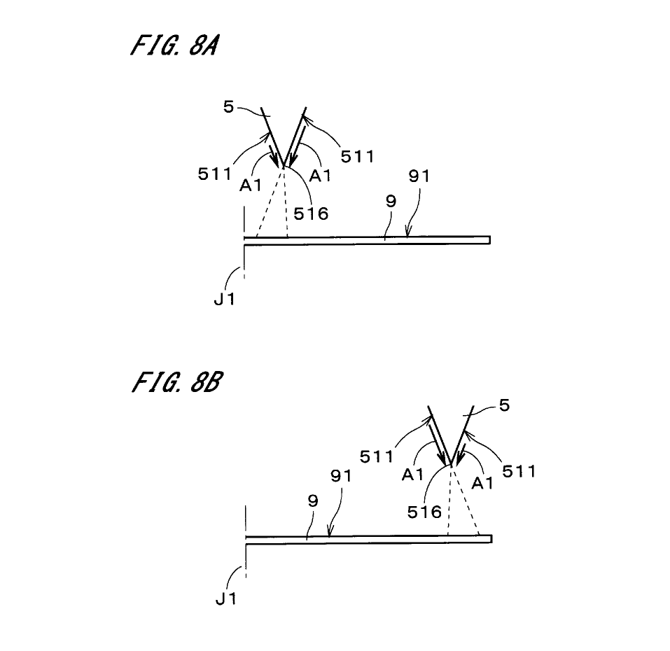

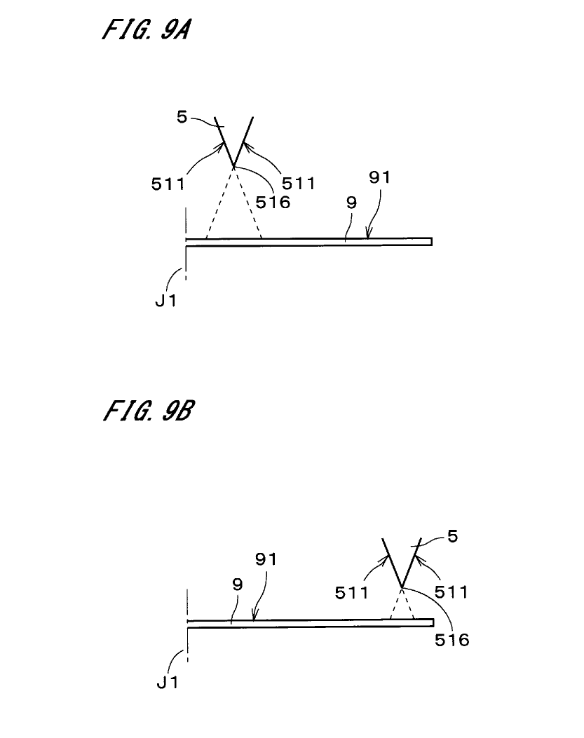

In the substrate processing apparatus 1, it is not always needed that the respective flow rates of the gases in the two gas ejection ports 512 should be equal to each other. As shown in FIGS. 8A and 8B, for example, in a case where the flow rate of gas flowing along one of the guide surfaces 511 is larger than that of gas flowing along the other guide surface 511, the droplets are discharged toward an area on the upper surface 91, which is different from the area directly below the lower end edge 516, in accordance with the difference in the flow rate of the gas between both the guide surfaces 511. In FIGS. 8A and 8B, the flow rate of the gas flowing along each of the guide surfaces 511 is indicated by the length of the arrow Al. Further, a range in which the droplets are dispersed (spread) is indicated by broken lines (the same applies to FIGS. 9A and 9B described later).

Thus, in the substrate processing apparatus 1, the gas flow rate adjusting part 412 for adjusting the flow rate of the gas ejected from the gas ejection port 512 is provided individually in each of the two gas ejection ports 512 and the control part 10 controls the two gas flow rate adjusting parts 412, to thereby change a discharge direction of the droplets. Even if the movement range of the nozzle part 5 by the nozzle moving mechanism 43 is limited, and the like, it is possible to discharge the droplets from the nozzle part 5 toward a wide range of the upper surface 91. Further, the control part 10 may gradually change the respective flow rates of the gases ejected from the two gas ejection ports 512 while the droplets spatter from the nozzle part 5, to thereby change the discharge direction of the droplets. This makes it possible, for example, to move an area in which the droplets are dispersed on the upper surface 91, to some degree, in a state where the position of the nozzle part 5 is held constant. The above-described method of changing the discharge direction of the droplets may be used in a later-described nozzle part 5b shown in FIG. 11.

The droplets discharged from the nozzle part 5 go toward the upper surface 91 while being spread in a direction perpendicular to the vertical direction and the lower end edge 516. Therefore, as shown in FIGS. 9A and 9B, the nozzle up-and-down moving mechanism 44 (see FIG. 1) may change the position of the nozzle part 5 in the vertical direction, to thereby change the size of the area in which the droplets are dispersed on the upper surface 91, i.e., the discharge area (the same applies to the later-described nozzle parts 5a and 5b shown in FIGS. 10 and 11, respectively). In FIGS. 9A and 9B, the height (the position in the vertical direction) of the nozzle part 5 is changed in accordance with the position of the nozzle part 5 in a radial direction around the rotation axis J1. It thereby becomes possible to change the amount of droplets spattering in a unit of area on the upper surface 91. Further, it also becomes possible to change the size of the discharge area and the speed at which the droplets collide with the upper surface 91 (the strength in the physical cleaning, or energy given to the upper surface 91). As a result, it is possible to increase the degree of freedom in the processing performed by the substrate processing apparatus 1, such as a change in the degree of processing in each process step, and the like).

FIG. 10 is a view showing a nozzle part 5a in accordance with the second preferred embodiment of the present invention. The nozzle part 5a of FIG. 10 has an outer shape with a lower part having a substantially conical shape around a predetermined central axis C1 and an upper part having a cylindrical shape. The nozzle part 5a includes a guide surface 531, an annular ejection port 532, a processing liquid supply port 533, a gas chamber 534, a processing liquid chamber 535, an auxiliary gas ejection port 537, and an auxiliary gas connecting passage 538. In the nozzle part 5a of FIG. 10, the number of each of these constituent elements is only one. The guide surface 531 is a substantially conical surface around the central axis C1. A lower-side end portion of the guide surface 531 has an annular lower end edge 536 around the central axis C1. The annular lower end edge 536 is also an edge of the auxiliary gas ejection port 537.

In the substrate processing apparatus 1 provided with the nozzle part 5a, two gas supply pipes 411 and one processing liquid supply pipe 421 are provided. The two gas supply pipes 411 are connected to the gas chamber 534 and the auxiliary gas connecting passage 538, respectively. The processing liquid supply pipe 421 is connected to the processing liquid chamber 535. The guide surface 531 is a smooth surface which is continuous from the lower end edge 536 to the inside of the gas chamber 534, except a portion of guide surface 531, which corresponds to the processing liquid supply port 533. The annular ejection port 532 around the central axis C1 is formed by a portion of the guide surface 531 between the processing liquid supply port 533 and the gas chamber 534 and a surface facing the portion at equal distance, and continuous from the gas chamber 534. With the supply of gas from the gas supply part 41 (see FIG. 1) to the inside of the gas chamber 534, the gas is ejected from the annular ejection port 532 along the guide surface 531. In other words, the gas is ejected in a direction along the guide surface 531 which is a substantially conical surface in which a top portion is positioned lower than a base portion, from the base portion toward the top portion. A gas flow flowing along the guide surface 531 toward the lower end edge 536 is thereby formed.

Further, the auxiliary gas ejection port 537 is formed by a cylindrical surface extending along the central axis C1. The auxiliary gas ejection port 537 is continuous from the auxiliary gas connecting passage 538 and opened in the vicinity of the top portion. In other words, the auxiliary gas ejection port 537 is provided in the vicinity of the top portion. With the supply of gas from the gas supply part 41 to the auxiliary gas connecting passage 538, the gas is ejected from the auxiliary gas ejection port 537 along the central axis C1. For example, the flow rate of the gas ejected from the auxiliary gas ejection port 537 is smaller than that of the gas ejected from the annular ejection port 532. The processing liquid supply port 533 is annular around the central axis C1 and formed by two cylindrical surfaces extending along the central axis C1 and in parallel with each other. The processing liquid supply port 533 is continuous from the processing liquid chamber 535 and opened at the guide surface 531. With the supply of a processing liquid from the processing liquid supply part 42 to the inside of the processing liquid chamber 535, the processing liquid is supplied from the processing liquid supply port 533 to between the above-described gas flow and the guide surface 531.

In the manufacture of the nozzle part 5a, a first member 541 having a tubular shape around the central axis C1 is inserted into a second member 542 having a substantially tubular shape, and the second member 542 is inserted into a third member 543 having a substantially tubular shape. The guide surface 531 includes part of an outer peripheral surface of the first member 541 and part of an outer peripheral surface of the second member 542. The annular ejection port 532 and the gas chamber 534 are formed by part of the outer peripheral surface of the second member 542 and part of an inner peripheral surface of the third member 543. The processing liquid supply port 533 and the processing liquid chamber 535 are formed by part of the outer peripheral surface of the first member 541 and part of an inner peripheral surface of the second member 542.

The auxiliary gas ejection port 537 and the auxiliary gas connecting passage 538 are formed by an inner peripheral surface of the first member 541. The nozzle part 5a (the first to third members 541 to 543 thereof) is formed of, for example, polytetrafluoroethylene (PTFE) or quartz (the same applies to the later-described nozzle part 5b shown in FIG. 11).

In the nozzle part 5a of FIG. 10, a gas flow flowing along the guide surface 531 is formed of the gas ejected from the annular ejection port 532, and a processing liquid is supplied from the processing liquid supply port 533 to between the gas flow and the guide surface 531. The processing liquid is spread between the gas flow and the guide surface 531 to form a thin film flow, and spatters at the lower end edge 536, away from the guide surface 531.

Herein, paying attention to the processing liquid spread by the gas ejected from part of the annular ejection port 532 and spattering from the lower end edge 536, the gas flow ejected from another part of the annular ejection port 532 and flowing along the guide surface 531 collides with the processing liquid in the vicinity of the lower end edge 536. In other words, part of the annular ejection port 532 serves as a first gas ejection port which forms the gas flow that is to carry the processing liquid as the thin film flow toward the lower end edge 536, and another part of the annular ejection port 532 serves as a second gas ejection port which forms the gas flow that is to collide with the processing liquid spattering from the lower end edge 536. A lot of droplets having a uniform particle diameter are thereby generated. It can be understood that in the nozzle part 5a, the thin film flows of the processing liquids collide with each other in the vicinity of the lower end edge 536.

Thus, in the nozzle part 5a of FIG. 10, a lot of droplets having a uniform particle diameter can be discharged, and in the substrate processing apparatus 1 having the nozzle part 5a, the substrate 9 can be appropriately processed. Further, since the nozzle part 5a has the auxiliary gas ejection port 537 which ejects the gas along the central axis C1, it is possible to easily change the state of the droplets (for example, the particle diameter of the droplets, a discharge speed, and the like) discharged toward the substrate 9.

FIG. 11 is a view showing a nozzle part 5b in accordance with the third preferred embodiment of the present invention. The nozzle part 5b of FIG. 11 includes two guide surfaces 551, two gas ejection ports 552, two processing liquid supply ports 553, two gas connecting passages 554, and two processing liquid connecting passages 555. The two guide surfaces 551 respectively include an inner peripheral surface and an outer peripheral surface of a tubular guiding part 550 around the predetermined central axis C1. The tubular guiding part 550 is an end portion of a tubular member 561. In the tubular guiding part 550, a thickness in the radial direction gradually decreases as it goes away from a center portion of the tubular member 561. In other words, assuming that the center portion side of the tubular member 561 is one end in the tubular guiding part 550, a wall thickness gradually decreases as it goes from the one end toward the other end. In the present preferred embodiment, the two guide surfaces 551 are substantially truncated cone surfaces around the central axis C1. A lower-side end portion of each guide surface 551 is the other end of the tubular guiding part 550 and has an annular lower end edge 556 around the central axis C1. The respective lower end edges 556 of the two guide surfaces 551 are almost coincident with each other. In FIG. 11, though a diameter of one of the two guide surfaces 551 gradually decreases as it goes toward the lower end edge 556, and a diameter of the other guide surface 551 gradually increases as it goes toward the lower end edge 556, for example, the respective diameters of the two guide surfaces 551 may gradually increase or decrease as they go toward the lower end edge 556.

In the substrate processing apparatus 1 provided with the nozzle part 5b, two gas supply pipes 411 and two processing liquid supply pipes 421 are provided. The two gas supply pipes 411 are connected to two gas connecting passages 554, respectively. The two processing liquid supply pipes 421 are connected to two processing liquid connecting passages 555, respectively. Each of the guide surfaces 551 is a smooth surface which is continuous from the lower end edge 556 to the gas connecting passage 554, except a portions of the guide surface 551, which corresponds to the processing liquid supply port 553. Each of the gas ejection ports 552 is annular around the central axis C1. The gas ejection port 552 is formed by a portion of the guide surface 551 between the processing liquid supply port 553 and the gas connecting passage 554 and a surface facing the portion at equal distance, and continuous from the gas connecting passage 554. With the supply of gas from the gas supply part 41 (see FIG. 1) to the inside of the gas connecting passage 554, the gas is ejected from the gas ejection port 552 along the guide surface 551. In other words, the gas is ejected in a direction along the guide surface 551 which is a substantially truncated cone surface, from the above-described one end of the tubular guiding part 550 toward the other end thereof. A gas flow flowing along the guide surface 531 toward the lower end edge 556 is thereby formed.

Each of the processing liquid supply ports 553 is annular around the central axis C1 and formed by two cylindrical surfaces extending along the central axis C1 and in parallel with each other. The processing liquid supply port 553 is continuous from the processing liquid connecting passage 555 and opened at the guide surface 551. With the supply of a processing liquid from the processing liquid supply part 42 to the inside of the processing liquid connecting passage 555, the processing liquid is supplied from the processing liquid supply port 553 to between the above-described gas flow and the guide surface 551. The processing liquid is spread between the gas flow and the guide surface 551 to form a thin film flow, and spatters at the lower end edge 556, away from the guide surface 551.

Herein, as described earlier, in the nozzle part 5b, the two guide surfaces 551 are provided and both the guide surfaces 551 share the lower end edge 556. Paying attention to the processing liquid flowing along the one guide surface 551 and spattering from the lower end edge 556, the gas flow flowing along the other guide surface 551 collides with the processing liquid in the vicinity of the lower end edge 556. In other words, assuming that one of the two gas ejection ports 552 is regarded as a first gas ejection port which forms the gas flow that is to carry the processing liquid as the thin film flow toward the lower end edge 556, the other gas ejection port is a second gas ejection port which forms the gas flow that is to collide with the processing liquid spattering from the lower end edge 556. A lot of droplets having a uniform particle diameter are thereby generated. It can be understood that in the nozzle part 5b, the thin film flows of the processing liquids flowing along the two guide surfaces 551 collide with each other in the vicinity of the lower end edge 556.

Thus, in the nozzle part 5b of FIG. 11, a lot of droplets having a uniform particle diameter can be discharged, and in the substrate processing apparatus 1 having the nozzle part 5b, the substrate 9 can be appropriately processed. Further, in the nozzle part 5b, since the annular lower end edge 556 is in parallel with the upper surface 91 of the substrate 9, it is possible to easily perform uniform processing on the entire upper surface 91.

In the above-described substrate processing apparatus 1, various modifications can be made.

In the nozzle part 5 having the main-body plate 51 shown in FIG. 4, for example, an auxiliary gas ejection port which is long in the plate thickness direction may be provided between lower end edges of the two guide surfaces 511. In this case, respective lower end edges of the two guide surfaces 511 are provided in parallel with and in proximity to each other.

In the nozzle part 5 of FIG. 4 which is provided with the two guide surfaces 511, the processing liquid supply port 513 in one of the guide surfaces 511 may be omitted. Similarly, in the nozzle part 5b of FIG. 11 which is provided with the two guide surfaces 551, the processing liquid supply port 553 in the guide surface 551 including one of the inner peripheral surface and the outer peripheral surface of the tubular guiding part 550 may be omitted. In either case, by causing the gas flow flowing along the one guide surface 511 or 551 to collide with the processing liquid supplied from the processing liquid supply port 513 or 553 in the other guide surface 511 or 551 and spattering from the lower end edge 516 or 556, it is possible to discharge a lot of droplets having a uniform particle diameter. Depending on a design of the nozzle part, the guide surface which guides the gas flow that is to collide with the spattering processing liquid may be omitted. From the viewpoint of efficiently generating a lot of droplets, it is preferable that the processing liquid supply port 513 or 553 which supplies the processing liquid to between the one guide surface 511 or 551 and the gas flow flowing along the one guide surface 511 or 551 should be also provided in the one guide surface 511 or 551.

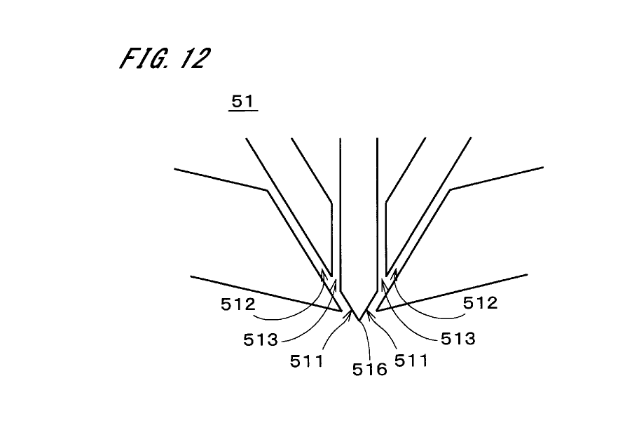

In a cross section perpendicular to the lower end edge 516 in the nozzle part 5 and a cross section including the central axis C1 in the nozzle part 5a or 5b, the shape of the guide surface 511, 531, or 551 may be bent. Further, as shown in FIG. 12, a lower end of the gas ejection port 512, i.e., a lower end of a surface facing the guide surface 511 at equal distance may be arranged in the vicinity of an upper side of the lower end edge 516. The gas ejection port 512 which forms the gas flow flowing along the guide surface 511 can be achieved in various manners (the same applies to the nozzle parts 5a and 5b). Further, in the exemplary case of FIG. 12, the gas ejection port 512 is opened directly in a side surface of the main-body plate 51 which is a plate-like member, and the processing liquid supply port 513 is opened indirectly in the side surface through part of the gas ejection port 512.

In the substrate processing apparatus 1, different kinds of gases may be supplied from the two gas supply pipes 411 to the nozzle part 5, 5a, or 5b. Similarly, different kinds of processing liquids may be supplied from the two processing liquid supply pipes 421 to the nozzle part 5 or 5b.

The substrate rotating mechanism which rotates the substrate 9 may be, for example, a mechanism in which an annular stator part including a plurality of coils rotates a rotor part including an annular permanent magnet in a floating state, and the like, as well as the motor for rotating the shaft. Further, the nozzle moving mechanism may be a mechanism which linearly moves the nozzle part, and the like, as well as the mechanism which rotates the nozzle part attached to the arm.

The substrate to be processed in the substrate processing apparatus 1 is not limited to a semiconductor substrate, but a glass substrate or any other substrate may be used.

The configurations in the above-discussed preferred embodiments and variations may be combined as appropriate only if those do not conflict with one another.

While the invention has been shown and described in detail, the foregoing description is in all aspects illustrative and not restrictive. It is therefore understood that numerous modifications and variations can be devised without departing from the scope of the invention.

### REFERENCE SIGNS LIST

1 Substrate processing apparatus
5, 5a, 5b Nozzle part
9 Substrate
10 Control part
21 Spin motor
43 Nozzle moving mechanism
44 Nozzle up-and-down moving mechanism
51 Main-body plate
91 Upper surface
412 Gas flow rate adjusting part
422 Processing liquid flow rate adjusting part
511, 531, 551 Guide surface
512, 552 Gas ejection port
513, 533, 553 Processing liquid supply port
516, 536, 556 Lower end edge
532 Annular ejection port
537 Auxiliary gas ejection port
550 Tubular guiding part
C1 Central axis

1. A substrate processing apparatus, comprising:
a substrate rotating mechanism for rotating a substrate;
a nozzle part for discharging droplets of a processing liquid toward a main surface of said substrate; and
a nozzle moving mechanism for moving said nozzle part in a direction along said main surface,
wherein said nozzle part comprises:
a guide surface;
a first gas ejection port for ejecting gas along said guide surface, to thereby form a first gas flow flowing along said guide surface;
a processing liquid supply port provided in said guide surface, for supplying said processing liquid to between said first gas flow and said guide surface; and
a second gas ejection port for forming a second gas flow which is to collide with said processing liquid spattering from an end portion of said guide surface in the vicinity of said end portion of said guide surface.

2. The substrate processing apparatus according to claim 1, wherein
said guide surface is a conical surface around a predetermined central axis,
said processing liquid supply port is annular around said central axis,
an annular ejection port around said central axis is provided and gas is ejected from said annular ejection port in a direction along said conical surface from a base portion of said conical surface toward a top portion thereof, and
a part of said annular ejection port serves as said first gas ejection port and another part of said annular ejection port serves as said second gas ejection port.

3. The substrate processing apparatus according to claim 2, wherein
said nozzle part further comprises an auxiliary gas ejection port provided in the vicinity of said top portion of said conical surface, for ejecting gas along said central axis.

4. The substrate processing apparatus according to claim 1, wherein
said nozzle part further comprises another guide surface,
said guide surface has a linear edge at said end portion,
said another guide surface has another edge in parallel with said edge of said guide surface and in proximity to said edge or coincident with said edge, and
said second gas ejection port ejects gas in a direction along said another guide surface from an opposite side of said another edge of said another guide surface toward said another edge.

5. The substrate processing apparatus according to claim 4, wherein
said guide surface and said another guide surface include part of a side surface of a plate-like member, and each of said first gas ejection port, said processing liquid supply port, and said second gas ejection port is a slit opened in at least one main surface of said plate-like member and said side surface thereof.

6. The substrate processing apparatus according to claim 1, wherein
said nozzle part further comprises a tubular guiding part around a predetermined central axis,
in said tubular guiding part, a wall thickness gradually decreases as it goes from one end toward the other end thereof,
one of an inner peripheral surface and an outer peripheral surface of said tubular guiding part is included in said guide surface and the other is included in another guide surface,
said guide surface has an annular edge at said other end,
said first gas ejection port and said processing liquid supply port are annular around said central axis,
said first gas ejection port ejects gas in a direction along said guide surface from said one end of said tubular guiding part toward said other end thereof,
said second gas ejection port is annular around said central axis, and
said second gas ejection port ejects gas in a direction along said another guide surface from said one end of said tubular guiding part toward said other end thereof.

7. The substrate processing apparatus according to claim 4, wherein
said edge of said guide surface is in parallel with said main surface of said substrate.

8. The substrate processing apparatus according to claim 4, wherein
said nozzle part further comprises another processing liquid supply port provided in said another guide surface, for supplying a processing liquid to between said second gas flow and said another guide surface.

9. The substrate processing apparatus according to claim 1, further comprising:
a droplet diameter changing part for changing a particle diameter of droplets to be discharged onto said main surface of said substrate from said nozzle part.

10. The substrate processing apparatus according to claim 9, wherein
said droplet diameter changing part adjusts a flow rate of gas from said first gas ejection port, or adjusts a flow rate of said processing liquid from said processing liquid supply port.

11. The substrate processing apparatus according to claim 4, further comprising:
a first gas flow rate adjusting part for adjusting a flow rate of gas to be ejected from said first gas ejection port;
a second gas flow rate adjusting part for adjusting a flow rate of gas to be ejected from said second gas ejection port; and
a control part for controlling said first gas flow rate adjusting part and said second gas flow rate adjusting part, to thereby change a discharge direction of droplets.

12. The substrate processing apparatus according to claim 11, wherein
said control part changes said discharge direction while said droplets are spattering from said nozzle part.

13. The substrate processing apparatus according to claim 1, further comprising:
a nozzle up-and-down moving mechanism for moving said nozzle part up and down in a vertical direction perpendicular to said main surface of said substrate.

14. The substrate processing apparatus according to claim 13, wherein
said nozzle up-and-down moving mechanism changes a position of said nozzle part in said vertical direction, to thereby change the size of an area in which droplets are to be dispersed on said main surface.

15. The substrate processing apparatus according to claim 6, wherein
said edge of said guide surface is in parallel with said main surface of said substrate.

16. The substrate processing apparatus according to claim 6, wherein
said nozzle part further comprises another processing liquid supply port provided in said another guide surface, for supplying a processing liquid to between said second gas flow and said another guide surface.

17. The substrate processing apparatus according to claim 6, further comprising:
a first gas flow rate adjusting part for adjusting a flow rate of gas to be ejected from said first gas ejection port;
a second gas flow rate adjusting part for adjusting a flow rate of gas to be ejected from said second gas ejection port; and
a control part for controlling said first gas flow rate adjusting part and said second gas flow rate adjusting part, to thereby change a discharge direction of droplets.
